(19) United States
(12) Patent Application Publication
(10) Pub. No.: US 2012/0314150 A1
(43) Pub. Date: Dec. 13, 2012

(54) ARRAY SUBSTRATE, MANUFACTURING METHOD THEREOF AND LIQUID CRYSTAL DISPLAY

(75) Inventors: Liang SUN, Beijing (CN); Zhaohui HAO, Beijing (CN); Chunxia MENG, Beijing (CN); Ying QIN, Beijing (CN); Seungmoo RIM, Beijing (CN)

(73) Assignees: BEIJING BOE DISPLAY TECHNOLOGY CO., LTD., Beijing (CN); BOE TECHNOLOGY GROUP CO., LTD., Beijing (CN)

(21) Appl. No.: 13/490,782

(22) Filed: Jun. 7, 2012

(30) Foreign Application Priority Data
Jun. 8, 2011 (CN) 201110152612.9

(51) Int. Cl. G02F 1/136; H01L 33/08

(52) U.S. Cl. 349/43; 438/34; 257/E33.065

(57) ABSTRACT

An array substrate is disclosed. The array substrate comprises a plurality of gate lines, a plurality of data lines, and a plurality of pixel units defined by the gate lines and the data lines and arranged in an array, each of the pixel units comprising a thin film transistor (TFT) for switching the pixel unit and a driving electrode for driving liquid crystal, and the driving electrode being formed with slit-shaped openings. The two corresponding pixel units respectively provided on two sides of the gate line are different from each other in structure, and the pixel unit on one side of the gate line can be obtained by rotating the pixel unit on the other side of the gate line by 180° respect to the central point of the section of the gate line between the two pixel units.

### BACKGROUND

Embodiments of the present disclosure relate to an array substrate, a manufacture method thereof, and a liquid crystal display.

A liquid crystal display panel (LCD panel) typically is formed of a color filter substrate, an array substrate and a liquid crystal layer sandwiched between the filter substrate and the array substrate. The proportion of the transmissive region to the total display region (i.e., aperture ratio) of the color filter substrate and the array substrate is an important factor for determining the transmissivity of the LCD panel. If the transmissivity of the LCD panel is decreased, the power consumption of the LCD panel may be increased and the manufacture costs of the LCD panel can be increased accordingly.

In order to improve the transmissivity of the LCD panel and further to reduce power consumption, LCD panel producers and many other companies involving the LCD industry have developed new display modes, new materials and new manufacture technologies to improve the transmissivity of the LCD panel. Generally, in structure a pixel layer is a final layer of the array substrate of the LCD panel. The pixel layer controls the electric field together with the common electrode layer to adjust the alignment of liquid crystal molecules of the LCD panel. In addition, the layout of the pixel layer has an important influence on optical properties of the LCD panel, such as the transmissivity of the LCD panel and the like.

FIG. 1 is a structural view showing the pixel layer in a convention technology. In FIG. 1, the reference number “10” denotes a gate line or a common electrode line of the LCD panel. Although FIG. 1 does not distinguish the gate line from the common electrode line, the gate line and the common electrode line are separated from and parallel to each other in practice. The reference number “20” denotes a data line, “C” denotes a thin film transistor (TFT) for controlling a corresponding pixel unit, “D” denotes the conductive film region of the pixel layer, and “E” and “F” denote two groups of slit-shaped openings in different orientations, respectively. The slit-shaped openings are formed in the conductive film of the pixel layer by photolithography and etching technologies. “G” denotes the region in which two groups of the slit-shaped openings in different orientations meet with (or adjoin) each other. As shown in FIG. 1, such meeting region is located within a pixel unit row or between two adjacent rows of pixels units. “H” denotes a pixel unit.

During displaying, in each pixel unit, the voltage applied on the pixel layer is changed under the control of the TFT according to the display contents, so that the electric field between the pixel layer and the common layer is changed, and in turn the distribution of the electric field lines entering the liquid crystal layer through the slit-shaped openings of the pixel layer are changed; in this way, the liquid crystal molecules in the liquid crystal layer are deflected (orientated). It can be seen that the length of the slit-shaped openings in the pixel layer can directly influence the transmissive range of the pixel unit.

As shown in FIG. 1, the pixel units in the pixel layer have the same structure in the conventional technology. Two groups of slit-shaped openings in two different orientations are provided in each pixel unit, so that the liquid crystal molecules can be rotated in two directions and thus the view angles of the LCD panel can be widened. The slit-shaped openings are formed in the conductive film by photolithography and etching processes. In each group of the slit-shaped openings, the slit-shaped openings are parallel to one another. In addition, as shown in FIG. 1, the conductive film remains around each slit-shaped opening, and thus the structure in which each slit-shaped opening is surrounded or closed by the conductive film is obtained.

In the structure in which each slit-shaped opening is surrounded by the conductive film, the transmissive area of each pixel unit is determined by the lengths of the slit-shaped openings, and thus the aperture ratio of each pixel unit can be increased by increasing the lengths of each slit-shaped openings. Where the width of each pixel unit is kept constant, the increasing of the lengths of the slit-shaped openings results in the decrease of the width of the conductive film surrounding the slit-shaped openings. However, the decrease of the width of the conductive film surrounding the slit-shaped openings is limited by the characteristics of the photolithography and etching processes, which prevents the further improvement of the aperture ration of the pixel unit.

In addition, in the region where two groups of slit-shaped openings meet with or adjoin each other, it is generally required to reduce the lengths of the slit-shaped openings to avoid the slit-shaped openings of two different groups intersect with each other. In the conventional array substrate as shown in FIG. 1, since the slit-shaped openings in each pixel unit have two different orientations and all of the pixel units have the same structure, the meeting regions G are located not only within each pixel unit but also on the upper and lower side of each pixel unit. As described above, the lengths of the slit-shaped openings in the meeting region are required to be less, thus the aperture ration of the LCD is further decreased due to the large number of the meeting regions G.

### SUMMARY

According to an embodiment of the disclosure, an array substrate is provided. The array substrate comprises a plurality of gate lines, a plurality of data lines, and a plurality of pixel units defined by the gate lines and the data lines and arranged in an array, each of the pixel units comprising a thin film transistor (TFT) for switching the pixel unit and a driving electrode for driving liquid crystal, and the driving electrode being formed with slit-shaped openings. The two corresponding pixel units respectively provided on two sides of the gate line are different from each other in structure, and the pixel unit on one side of the gate line can be obtained by rotating the pixel unit on the other side of the gate line by 180° respect to the central point of the section of the gate line between the two pixel units.

According to another embodiment of the disclosure, a manufacture method of an array substrate is provided. The array substrate comprises a plurality of gate lines, a plurality of data lines and a plurality of pixel units defined by the gate lines and the data lines and arranged in an array, each of the pixel units comprising a thin film transistor (TFT) for driving the pixel unit and a driving electrode which is for driving liquid crystal, and the driving electrode being formed with slit-shaped openings. The method comprises: forming the driving electrode with a conductive film and the slit-shaped openings in the driving electrode, so that the two corresponding pixel units respectively provided on two sides of the gate line are different from each other in structure, and the pixel unit on one side of the gate line can be obtained by rotating the pixel unit on the other side of the gate line by 180° respect to the central point of the section of the gate line between the two pixel units.

According to another embodiment of the disclosure, a liquid crystal display is provided. The liquid crystal display comprises the above-described array substrate.

Further scope of applicability of the present disclosure will become apparent from the detailed description given hereinafter. However, it should be understood that the detailed description and specific examples, while indicating preferred embodiments of the disclosure, are given by way of illustration only, since various changes and modifications within the spirit and scope of the disclosure will become apparent to those skilled in the art from the following detailed description.

### BRIEF DESCRIPTION OF THE DRAWINGS

The present disclosure will become more fully understood from the detailed description given hereinafter and the accompanying drawings which are given by way of illustration only, and thus are not limitative of the present disclosure and wherein:

FIG. 1 is a structural view showing a pixel layer in the conventional technology;

FIG. 2 is a structural view showing an array substrate according to an embodiment of the disclosure;

FIG. 3 is a structural view showing an array substrate according to an embodiment of the disclosure, in which one side of the slit-shaped opening is not provided with the conductive film.

FIG. 4 is an enlarged view showing the “Q” region in FIG. 3.

### DETAILED DESCRIPTION

Hereinafter, one or more embodiments of the disclosure will be described in detail with reference to the accompanying drawings so that the objects, technical solutions and advantages of the embodiments of the disclosure will become more apparent. It should be noted that the embodiments described below merely are a portion of but not all of the embodiments of the disclosure, and thus various modifications, combinations and alterations may be made on basis of the described embodiments without departing from the spirit and scope of the disclosure.

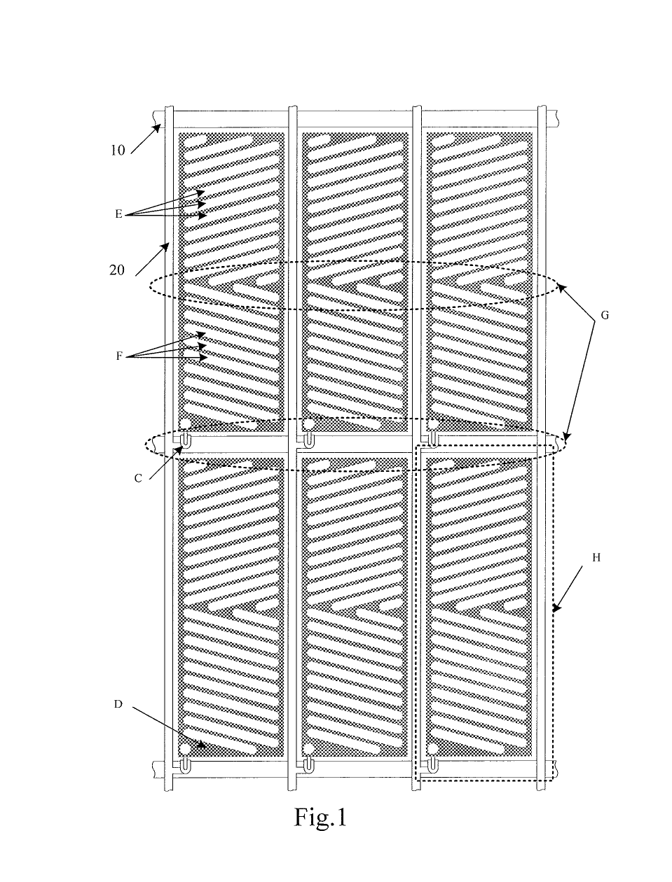

In one or more embodiments of the disclosure, the structure of the pixel layer (pixel unit) of the LCD array substrate is modified to improve the utilization efficiency of the spaces within a pixel unit and between adjacent pixel units and thus to increase the aperture ratio/transmissivity of the LCD panel compared with the conventional technology as shown in FIG. 1 for example.

The structure of the embodiments of the disclosure may be applied to various types of LCD panel, such as advanced-super dimensional switching (AD-SDS) mode, in-plane switching (IPS) mode, multi-domain vertical alignment (MVA) mode, patterned vertical alignment (PVA) mode and the like.

In an AD-SDS mode LCD, in each pixel unit a parallel electric field generated along the edges of pixel electrodes in a same pixel electrode layer and a vertical electric field generated between the pixel electrode layer and a common electrode layer form a multi-dimensional electric field, so that all of the liquid crystal molecules provided between the pixel electrodes and directly above the pixel electrodes can be deflected and thus the efficiency of the LCD panel can be improved and the transmissivity can be increased as well. In addition, the AD-SDS technology can improve the display quality of the LCD and have the advantages of high transmissivity, wide view angles, high aperture ratio, low chromatic aberration, low response time, no push mura, and the like.

Two or more different pixel unit structures are employed in the array substrate of the LCD panel in one or more embodiments of the disclosure. With the interlace arrangement of the different pixel unit structures, the space utilization efficiency of the pixel layer can be improved and the aperture ratio of the LCD panel can be increased as well.

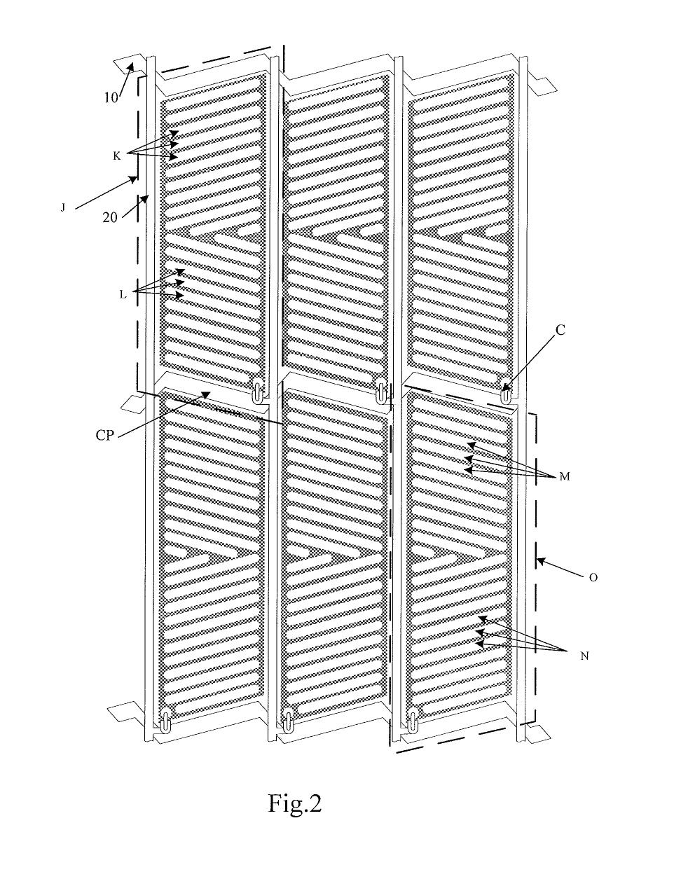

FIG. 2 is a structural view showing an array substrate according to an embodiment of the disclosure. As shown in FIG. 2, the gate lines 10 extend in the transverse direction, and the data lines 20 extend in the vertical direction; the gate lines 10 and the data lines intersect with each other to define an array of pixel units. Each pixel unit comprises a thin film transistor (TFT) “C” as a switching element, a pixel electrode connected with the TFT, and a common electrode on a different level from the pixel electrode. The common electrode may be connected with a common electrode line (not shown) in one example, and generally the common electrode line may extend in parallel to a gate line. The pixel electrode and the common electrode are the examples of the first and second driving electrode for driving liquid crystal.

In the embodiment as shown in FIG. 2, in each pixel unit, the pixel electrode is on an upper layer, and the common electrode is on a lower layer. Slit-shaped openings in different orientations are provided in the conductive film for forming the pixel layer (pixel electrode) of each pixel unit of the array substrate so that the view angles can be widened. In FIG. 2, “J” and “O” respectively denote two different types of pixel unit structures. The orientation of the slit-shaped openings in the “K” region of the “J” type pixel unit is parallel to that in the “N” region of the “O” type pixel unit, and the orientation of the slit-shaped openings in the “L” region of the “J” type pixel unit is parallel to that in the “M” region of the “O” type pixel unit. That is, in this embodiment of the disclosure, the pixel units respectively provided on the two sides of each gate line are different from each other in structure, and the pixel unit on one side of the gate line can be obtained by rotating the pixel unit on the other side of the gate line by 180° with respect to the central point of the section of the gate line between the two pixel units. In addition, the gate line (and the common electrode line) in this embodiment are provided to parallel to the slit-shaped openings of the pixel units adjacent to the gate line (and the common electrode line) and thus have a zigzag (“Z”) shape.

According to this embodiment, the array substrate comprising pixel units with two different structures are employed instead of the conventional array substrate comprising pixel units with a same structure, and the pixel units of two different structures are alternately provided along the data line direction. In this way, the space occupying by the meeting regions on the upper and lower sides of one pixel unit can be decreased, and thus the space utilization efficiency can be improved and the reduction of the aperture ratio resulting from the meeting regions of the slit-shaped openings can be substantially reduced or avoided.

The slit-shaped openings formed in the conductive film of the pixel layer (pixel electrode) may have the conventional structure in which each of the slit-shaped openings is surrounded or closed by the conductive film. In another embodiment, the slit-shaped openings formed in the conductive film of the pixel layer may have a structure in which one side of the slit-shaped opening is opened, that is, this side is not closed by the conductive film. In this way, the length of the slit-shaped opening can be increased without changing the width of the pixel unit, and thus the transmissive range of the array substrate can be increased and the aperture ratio of the array substrate can be increased as well.

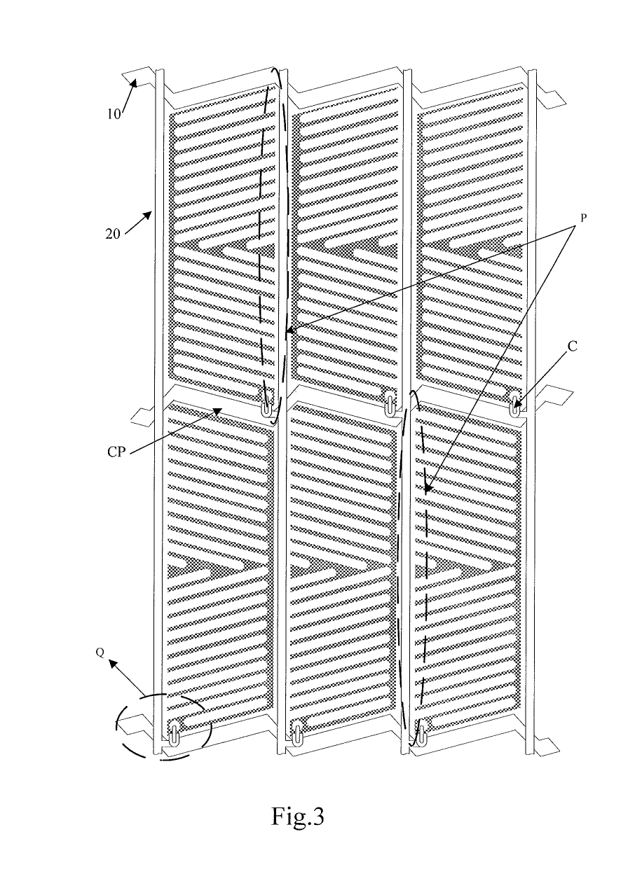

FIG. 3 is structural view showing an array substrate according to an embodiment of the disclosure, in which one side of the slit-shaped opening is opened. Based on the structure of the array substrate shown in FIG. 2, one side of the slit-shaped openings in the “P” region of each pixel unit in FIG. 3 is not provided with the conductive film of the pixel layer, that is, this side is opened. In this way, the length of the slit-shaped opening can be further increased. Therefore, the transmissive range of the array substrate can be further increased and the aperture ratio of the array substrate can be further increased as well.

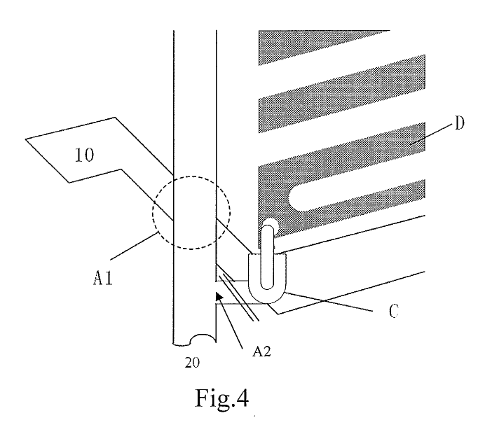

FIG. 4 is an enlarged view of the “Q” region in FIG. 3. Since the zigzag-shaped gate line 10 in the embodiment of the disclosure has an inclined portion, the array substrate can be easily repaired by a laser repairing method. Specifically, the gate line 10 cross and overlap with the data line 20 in the region A1 for one pixel unit; on the other hand, the connection portion (A2 as shown in FIG. 4) of the data line 20 and the TFT C does not overlap with the gate line 10 due to the inclined portion of the gate line 10, in this way, the data line 20 and the TFT C can be easily cut off at the position indicated by the double inclined lines from each other without damaging the gate line 10 when the defects such as bright spot and the like occur in the corresponding pixel unit. In addition, in the array substrate according to the embodiment of the disclosure, the loading of the data line 20 can be reduced due to the small overlapping region between the data line 20 and the gate line 10 and the loading of the data line after a repairing process can be reduced as well.

According to another embodiment of the disclosure, with each pixel unit, the array substrate shown in FIGS. 2-4 may be manufactured in the following steps: forming a common electrode, a gate line, and a gate electrode; forming a semiconductor layer of a thin film transistor; providing a data line and source and drain electrodes above the semiconductor layer; and providing a conductive film used as a pixel electrode with slit-shaped openings being formed in the pixel electrodes. In another embodiment, a common electrode line connected with the common electrode may be formed. The gate line and the common electrode line are provided to parallel to the slit-shaped openings adjacent to the gate line and common electrode line.

According to the above manufacture method of the embodiment, the pixel units respectively provided on two sides of the gate line are different from each other in structure, and the pixel unit on one side of the gate line can be obtained by rotating the pixel unit on the other side of the gate line by 180° with respect to the central point of the section of the gate line between the two pixel units.

According to the above manufacture method of the embodiment, the slit-shaped openings may have the structure in which the slit-shaped openings are surrounded by the conductive film, or the slit-shaped opening may have another structure in which one side of each slit-shaped opening is not provided with conductive film and opened.

According to the above manufacture method of the embodiment, the connection portion of the data line and the TFT may not overlap with the gate line for example.

The above manufacture method may further comprise the step of testing the electrical properties of the array substrate. If a short-circuit TFT is spotted through the electrical testing, the TFT can be cut off from the data line by a laser cutting process for example.

In the conventional array substrate in which the connection portion of the data line and the TFT overlaps with the gate line, the gate line tends to be damaged when the short-circuit TFT is cut off from the data line, it is difficult to minimize the overlapping region of the data line and the gate line after the repairing process and sometimes it is hardly to perform the repair process. However, in the array substrate as shown in FIG. 4, the damage to the gate line can be avoided when the short-circuit TFT is cut off from the data line, a small overlapping region between the data line 20 and the gate line 10 can be obtained after the cutting process, and unnecessary capacitance loading on the data line can be avoided.

It should be noted that the width, shape and position of the gate line and the data line in the embodiments of the disclosure are not limited as long as it is appropriate to make the connection portion of the data line and the TFT not overlap with the gate line. Therefore, the width, shape and position of the gate line 10 and the data line 20 may be changed or modified for the purpose of easy repairing and reducing the loading on the data line 20.

It should be noted that the portion comprising the pixel units shown in the accompanying drawings of the disclosure is a representative portion of the display area of the array substrate, and other portions of the active area of the array substrate may be identical to the portion shown in the drawings.

In another embodiment, similar to the structure as shown in FIGS. 2-4, in the exemplary array substrate, a pixel electrode and a common electrode as the first and second driving electrode for driving liquid crystal in each pixel unit are on different levers also; the pixel electrode is connected with the TFT of the pixel unit and on a lower level, the common electrode is on an upper level, and the common electrode has slit-shaped openings therein. Also, in this embodiment of the disclosure, the pixel units respectively provided on the two sides of each gate line are different from each other in structure, and the pixel unit on one side of the gate line can be obtained by rotating the pixel unit on the other side of the gate line by 180° with respect to the central point of the section of the gate line between the two pixel units; in addition, the gate line (and the common electrode line) in this embodiment may further be provided to parallel to the slit-shaped openings of the pixel units adjacent to the gate line (and the common electrode line) and therefore have a zigzag (“Z”) shape.

In the above embodiments, LCD panels of AD-SDS mode are taken for example. Another embodiment provides an exemplary LCD panel of IPS mode, in which a pixel electrode and a common electrode as first and second driving electrodes for driving liquid crystal in each pixel unit are provided on a same level; both the pixel electrode and the common electrode have slit-shaped openings, and the openings are interlaced or alternately arranged. Also, in this embodiment of the disclosure, the pixel units respectively provided on the two sides of each gate line are different from each other in structure, and the pixel unit on one side of the gate line can be obtained by rotating the pixel unit on the other side of the gate line by 180° with respect to the central point of the section of the gate line between the two pixel units; in addition, the gate line (and the common electrode line) in this embodiment may further be provided to parallel to the slit-shaped openings of the pixel units adjacent to the gate line (and the common electrode line) and therefore have a zigzag (“Z”) shape.

In one or more embodiments of the disclosure, by adjusting the layout within the pixel unit and alternately arranging the pixel units with different structures, the utilization efficiencies of the space within the pixel unit and the space between the pixel units can be improved, the aperture ratio of the LCD panel can be increased and thus the transmissivity of the LCD panel can be increased. In this way, the number or power of backlights can be reduced without reducing the brightness of the LCD panel, thus the power consumption of the LCD panel can be reduced and the manufacture costs of the LCD panel can be decreased.

In addition, a liquid crystal display is provided according to another embodiment of the disclosure. The liquid crystal display comprises the array substrate shown in FIG. 2 or FIG. 3, and an opposing substrate such as a color filter substrate. A liquid crystal layer is interposed between the array substrate and the opposing substrate. The array substrate, the opposing substrate, and the liquid crystal layer form an LCD panel. A backlight module is provided behind or under the LCD panel and may comprise fluorescent lamps or light-emitting diodes (LEDs) as light sources.

It should be appreciated that the embodiments described above are intended to illustrate but not limit the present disclosure. Although the present disclosure has been described in detail herein with reference to the preferred embodiments, it should be understood by those skilled in the art that the present disclosure can be modified and some of the technical features can be equivalently substituted without departing from the spirit and scope of the present disclosure.

What is claimed is:

1. An array substrate, comprising
a plurality of gate lines,
a plurality of data lines, and
a plurality of pixel units defined by the gate lines and the data lines and arranged in an array, each of the pixel units comprising a thin film transistor (TFT) for switching the pixel unit and a driving electrode for driving liquid crystal, and the driving electrode being formed with slit-shaped openings,
wherein the two corresponding pixel units respectively provided on two sides of the gate line are different from each other in structure, and the pixel unit on one side of the gate line can be obtained by rotating the pixel unit on the other side of the gate line by 180° respect to the central point of the section of the gate line between the two pixel units.

2. The array substrate according to claim 1, wherein each of the gate lines is parallel to the slit-shaped openings of the pixel units adjacent to the gate line.

3. The array substrate according to claim 2, wherein the slit-shaped openings of one pixel unit have a structure in which the slit-shaped openings are surrounded by a conductive film for forming the driving electrode.

4. The array substrate according to claim 2, wherein the slit-shaped openings of one pixel unit have a structure in which one side of the slit-shaped openings are not closed by a conductive film for forming the pixel electrode.

5. The array substrate according to claim 1, wherein a connection portion of each of the data lines and the TFT of one pixel unit does not overlap with the gate line corresponding to the pixel unit.

6. The array substrate according to claim 1, wherein the slit-shaped openings of each pixel unit comprise two groups of slit-shaped openings in different orientations.

7. The array substrate according to claim 1, wherein the array substrate further comprises a plurality of common electrode lines parallel to the gate lines.

8. A manufacture method of an array substrate, the array substrate comprising a plurality of gate lines, a plurality of data lines and a plurality of pixel units defined by the gate lines and the data lines and arranged in an array, each of the pixel units comprising a thin film transistor (TFT) for driving the pixel unit and a driving electrode which is for driving liquid crystal, and the driving electrode being formed with slit-shaped openings, the method comprising:
forming the driving electrode with a conductive film and the slit-shaped openings in the driving electrode, so that the two corresponding pixel units respectively provided on two sides of the gate line are different from each other in structure, and the pixel unit on one side of the gate line can be obtained by rotating the pixel unit on the other side of the gate line by 180° respect to the central point of the section of the gate line between the two pixel units.

9. The method according to claim 8, further comprising: forming the gate lines so that each of gate lines is parallel to the slit-shaped openings of the pixel units adjacent to the gate line.

10. The method according to claim 9, further comprising: forming the slit-shaped openings of each pixel unit so that the slit-shaped openings have a structure in which the slit-shaped openings are surrounded by the conductive film.

11. The method according to claim 9, further comprising: providing the slit-shaped openings of each pixel unit so that the slit-shaped openings have a structure in which one side of the slit-shaped opening is not closed by the conductive film.

12. The method according to claim 8, wherein a connection portion of each of the data lines and the TFT of one pixel unit does not overlap with the gate line corresponding to the pixel unit.

13. The method according to claim 8, further comprising: performing an electrical test on the array substrate to determine whether a short-circuit TFT exists, and if there exists a short-circuit TFT, cutting off the short-circuit TFT from the data line by a laser cutting process.

14. The method according to claim 8, further comprising: forming the slit-shaped openings of each pixel unit so that the slit-shaped opening comprises two slit-shaped openings in different orientations.

15. The method according to claim 8, further comprising: providing a plurality of common electrode lines so that the common electrode lines are parallel to the gate lines.

16. A liquid crystal display, comprising the array substrate according to claim 1.
